(19) United States
(12) Patent Application Publication
(10) Pub. No.: US 2007/0004076 A1
(43) Pub. Date: Jan. 4, 2007

(54) CMOS image sensor including two types of device isolation regions and method of fabricating the same

(76) Inventors: Seok-Ha Lee, Seoul (KR); Jae-Seob Roh, Anyang-si (KR); Jung-Hyun Nam, Suwon-si (KR); Hee-Guen Jeong, Yeongtong-gu (KR)

Correspondence Address: F. CHAU & ASSOCIATES, LLC, 130 WOODBURY ROAD, WOODBURY, NY, 11797, US

(21) Appl. No.: 11/401,716

(22) Filed: Apr. 11, 2006

(30) Foreign Application Priority Data
Apr. 11, 2005 (KR) 2005-29952

(51) Int. Cl. H01L 21/00; H01L 31/12

(52) U.S. Cl. 438/57; 257/83

(57) ABSTRACT

Provided are a complementary metal oxide semiconductor (CMOS) image sensor including two types of device isolation regions and a method of fabricating the same. The CMOS image sensor includes a first active region of a semiconductor substrate in which a photodiode is formed; a second active region of the semiconductor substrate connected to a first side of the first active region; a first device isolation region of the semiconductor substrate comprising an insulating layer that surrounds the second active region and bounds the first side of the first active region and a second side of the first active region disposed opposite to the first side of the first active region; and a second device isolation region of the semiconductor substrate bounding at least two opposite sides of the first active region without contacting the second active region, wherein the second device isolation region is doped with impurities

### CROSS-REFERENCE TO RELATED PATENT APPLICATION

This application claims priority to Korean Patent Application No. 10-2005-0029952, filed on Apr. 11, 2005, the disclosure of which is herein incorporated by reference in its entirety.

### BACKGROUND OF THE INVENTION

1. Technical Field

The present invention relates to an image sensor and a method of fabricating the same and, more particularly, to a complementary metal oxide semiconductor (CMOS) image sensor including photodiodes and a method of fabricating the same.

2. Description of the Related Art

Image sensors are semiconductor devices that convert optical images into electrical signals. In particular, complementary metal-oxide semiconductor (CMOS) image sensors use CMOS fabrication technology to create photosensitive devices that capture and process an optical image within a single integrated chip. A photodetector in CMOS image sensors is typically a photodiode.

Hereinafter, a conventional CMOS image sensor will be described with reference to FIGS. 1 and 2. Referring to FIGS. 1 and 2, the conventional CMOS image sensor includes an array of photodiodes 140 and control gates 162, 172, 180, and 185 for each of the photodiodes 140. The photodiodes 140 are divided into a first photodiode PD1, a second photodiode PD2, a third photodiode PD3, and a fourth photodiode PD4. The first photodiode PD1 and its control gates 162, 172, 180, and 185 form a pixel. All the individual pixels have basically the same structure.

The photodiodes 140 are formed in a portion of an active region 108 of a semiconductor substrate 105. The photodiodes 140 have a PN junction structure with a p-type impurity region 130 formed over an n-type impurity region 135. As shown in FIG. 2, the n-type impurity region 130 is formed over a deep p-type well 110.

The first photodiode PD1, for example, is insulated from the third photodiode PD3 by a device isolation region 115 to prevent signal interference or signal overflow that may occur therebetween. The device isolation region 115 is formed of an insulating layer, for example, a silicon oxide layer. As shown in FIG. 2, the device isolation region 115 is surrounded by a channel stop region 120. For example, the channel stop region 120 is a p-type impurity region.

When light is incident on the photodiodes 140, electric charges are generated. The generated electric charges move through the control gates 162, 172, 180, and 185. The control gates 162, 172, 180, and 185 comprise a reset gate 162 setting the potential of a floating diffusion region, a transfer gate 172 controlling the transmission of electric charges, a drive gate 180 functioning as a source follower, and a select gate 185 performing an addressing function, respectively.

A CMOS image sensor as illustrated in FIG. 2 may exhibit crystal defects at a boundary a₁ of the device isolation region 115. Such crystal defects may accumulate while the device isolation region 115 is formed or be introduced in subsequent processes. The crystal defects, which act as traps capturing electrons, may become defect components or noise components of each pixel, increasing the dark current i.e., the current that continues to flow in the photodiode when there is no incident light. As a result, the crystal defects of the device isolation. region 115 can degrade the imaging characteristics of the CMOS image sensor.

### SUMMARY OF THE INVENTION

Exemplary embodiments of the present invention generally include complementary metal-oxide semiconductor (CMOS) image sensors that can suppress the generation of dark current and methods of fabricating CMOS image sensors.

According to an exemplary embodiment of the present invention, a CMOS image sensor includes: a first active region of a semiconductor substrate in which a photodiode is formed; a second active region of the semiconductor substrate connected to a first side of the first active region; a first device isolation region of the semiconductor substrate comprising an insulating layer that surrounds the second active region and bounds the first side of the first active region and a second side of the first active region disposed opposite to the first side of the first active region; and a second device isolation region of the semiconductor substrate bounding at least two opposite sides of the first active region without contacting the second active region, wherein the second device isolation region is doped with impurities.

According to another exemplary embodiment of the present invention, a CMOS image sensor includes: a plurality of active regions of a semiconductor substrate comprising first active regions arranged in rows and columns and second active regions interposed between the first active regions arranged in each row and connected to the first active regions; photodiodes formed in the first active regions; at least one control gate formed on each of the second active regions; a first device isolation region of the semiconductor substrate interposed between the second active regions and the photodiodes arranged in each row and formed of an insulating layer; and a second device isolation region of the semiconductor substrate interposed between the photodiodes arranged in each column and doped with impurities.

Each of the photodiodes may include an impurity region of a first conductivity type formed over an impurity region of a second conductivity type. The second device isolation region may be doped with the impurities of the first conductivity type. The impurities of the first conductivity type may be p-type impurities and the impurities of the second conductivity type may be n-type impurities.

According to another exemplary embodiment of the present invention, a method of fabricating a CMOS image sensor includes: forming a first device isolation region defining an active region in a semiconductor substrate by burying an insulating layer in the semiconductor substrate; defining photodiode regions disposed in one direction in the active region, forming a second device isolation region by doping regions between the photodiode regions with impurities, and forming an active region surrounded by the first device isolation region and the second device isolation region; and forming photodiodes in the photodiode regions.

The first device region may be formed by forming a trench in the semiconductor substrate, filling the trench with the insulating layer, and planarizing the insulating layer. The second device isolation region may be doped with impurities of a first conductivity type. Further, each of the photodiodes may include a region doped with the impurities of the first conductivity type and a region doped with impurities of a second conductivity type under the region doped with the impurities of the first conductivity type.

### BRIEF DESCRIPTION OF THE DRAWINGS

The present invention will become readily apparent to those of ordinary skill in the art when descriptions of exemplary embodiments thereof are read with reference to the accompanying drawings.

FIG. 1 is a plan view of a conventional complementary metal-oxide semiconductor (CMOS) image sensor.

FIG. 2 is a cross-sectional view of the CMOS image sensor of FIG. 1 taken along line A-A′.

FIG. 3 is a plan view of a CMOS image sensor according to an exemplary embodiment of the present invention.

FIG. 4 is a cross-sectional view of the CMOS image sensor of FIG. 3 taken along line A-A′.

FIG. 5 is a cross-sectional view of the CMOS image sensor of FIG. 3 taken along line B-B′.

FIG. 6 is a cross-sectional view of the CMOS image sensor of FIG. 3 taken along line C-C′.

FIGS. 7A through 9A are cross-sectional views of the CMOS image sensor of FIG. 3 taken along line A-A′ to illustrate a method of fabricating the CMOS image sensor according to an exemplary embodiment of the present invention.

FIGS. 7B through 9B are cross-sectional views of the CMOS image sensor of FIG. 3 taken along line B-B′ to illustrate a method of fabricating the CMOS image sensor according to another exemplary embodiment of the present invention.

### DETAILED DESCRIPTION OF EXEMPLARY EMBODIMENTS

Hereinafter, exemplary embodiments of the present invention will be described in detail with reference to the accompanying drawings. In the drawings, the size and relative sizes of layers and regions may be exaggerated for clarity. Like reference numerals refer to similar or identical elements throughout the description of the figures. It will be appreciated that “rows” and “columns” are interchangeable.

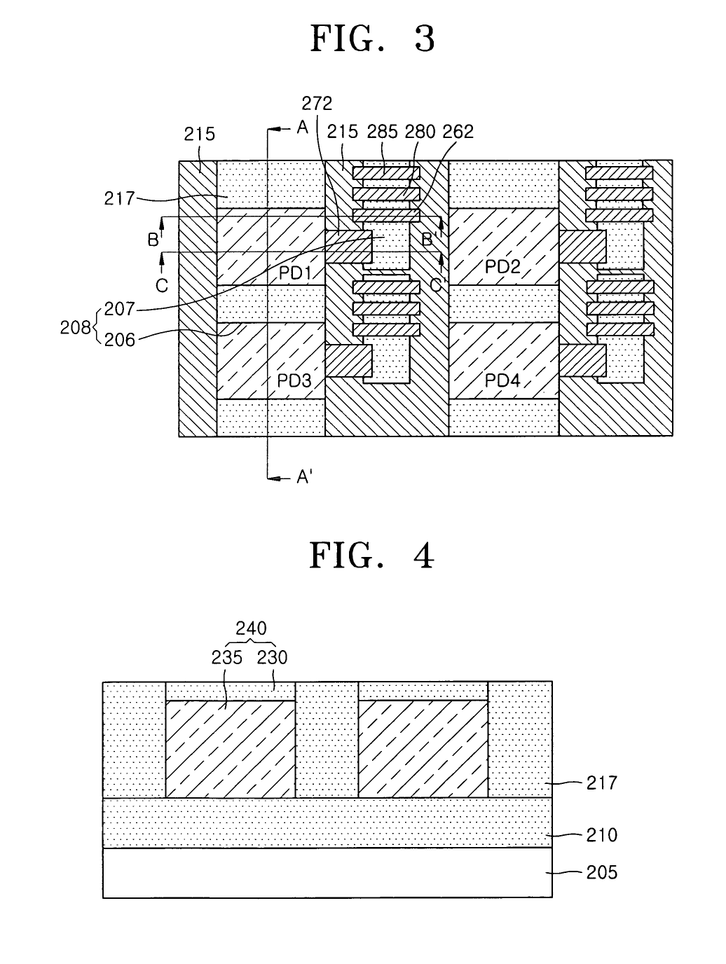

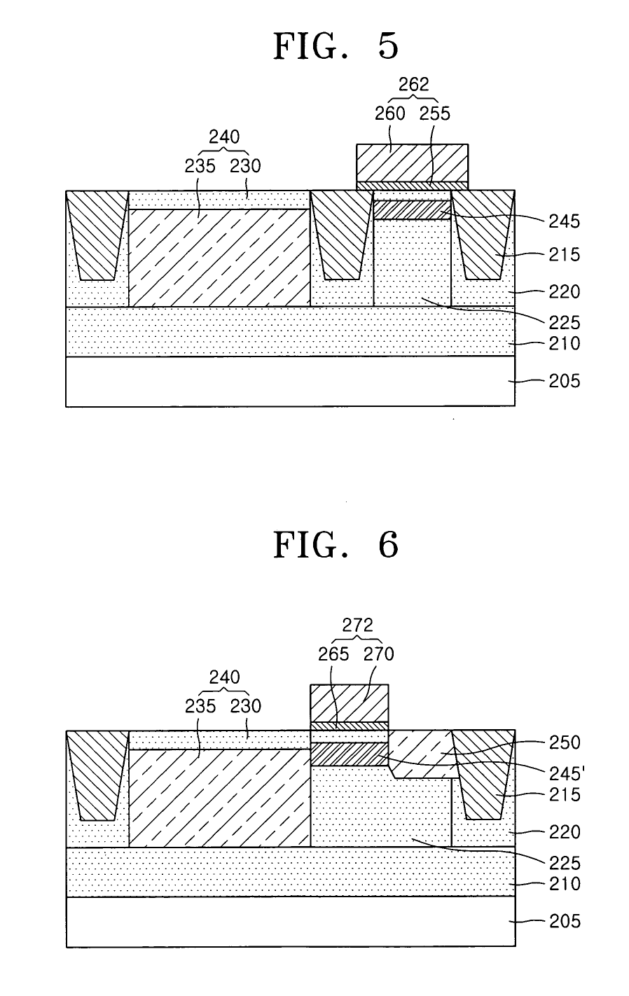

FIG. 3 is a plan view of a complementary metal-oxide semiconductor (CMOS) image sensor according to an exemplary embodiment of the present invention. FIG. 4 is a cross-sectional view of the CMOS image sensor of FIG. 3 taken along line A-A′. FIG. 5 is a cross-sectional view of the CMOS image sensor of FIG. 3 taken along line B-B′. FIG. 6 is a cross-sectional view of the CMOS image sensor of FIG. 3 taken along line C-C′.

Referring to FIGS. 3 through 6, the CMOS image sensor includes photodiodes 240 arranged in an array of rows and columns and the control gates 262, 272, 280 and 285 for each of the photodiodes 240. In the interests of clarity and simplicity, the photodiodes 240 are divided into a first photodiode PD1, a second photodiode PD2, a third photodiode PD3, and a fourth photodiode PD4. The first photodiode PD1, for example, and its control gates 262, 272, 280, and 285 form a pixel. All the individual pixels may have the same structure.

The photodiodes 240 are formed in an active region 208 of a semiconductor substrate, and the control gates 262, 272, 280, and 285 are formed on the active region 208. The active region 208, which will be described in detail later in this disclosure, is defined by a first device isolation region 215 and a second device isolation region 217 of the semiconductor substrate 205.

The photodiodes 240 may be formed in a first active region 206, and the control gates 262, 272, 280, and 285 may be formed on a second active region 207. The second active region 207 is connected to a side of the first active region 206. As shown in FIG. 3, the second active region 207 is interposed between the photodiodes 240 arranged in each row. It is to be understood that, since the rows and columns are interchangeable, the second active region 207 may be interposed between the photodiodes 240 arranged in each column.

Referring to FIG. 4, the photodiodes 240 may include a first conductive impurity region 230 and a second conductive impurity region 235, wherein the first conductive impurity region 230 is formed over the second conductive impurity region 235. The first conductive impurity region 230 may be a p-type impurity region, and the second conductive impurity region 235 may be an n-type impurity region. As shown in FIG. 4, the second conductive impurity region 235 is formed over a deep p-type well 210. P-type impurities include, but are not limited to, boron (B) or BF2, and n-type impurities may be arsenic (As), phosphorous (P), or the like.

As the cross-sectional view of the CMOS image sensor illustrates the photodiode 240 has a PN junction diode structure and that the photodiode 240 and the deep p-type well 210 have a PNP junction diode structure. The semiconductor substrate 205 may be doped with the n-type or p-type impurities. In an exemplary embodiment of the present invention, the semiconductor substrate 205 is doped with n-type impurities.

The second device isolation region 217 may be doped with impurities. In an exemplary embodiment of the present invention, the second device isolation region 217 forms a diode junction structure with the second conductive impurity regions 235 of the photodiodes 240. The second device isolation region 217 may be formed between the photodiodes 240 arranged in each column. For example, the second device isolation region 217 may be formed between the first photodiode PD1 and the third photodiode PD3 or between the second photodiode PD2 and the fourth photodiode PD4. The second device isolation region 217 is joined to the photodiodes 240 to form the diode junction structure and insulates.

In the case where the second conductive impurity region 235 is doped with the n-type impurities, the second device isolation region 217 may be doped with the p-type impurities. For example, the p-type impurities may be boron (B) or BF2. It will be understood that various p-type and n-type impurities are suitable for implementing the present invention. The second device isolation region 217 doped with the p-type impurities is interposed between the second conductive impurity regions 235, e.g., the n-type impurity regions, arranged in columns to form the NPN diode junction structure. In an exemplary embodiment of the present invention, the second device isolation region 217 maintains a reverse bias condition between the second conductive impurity regions 235, e.g., the n-type impurity regions, electrically insulating the second conductive impurity regions 235 from one another.

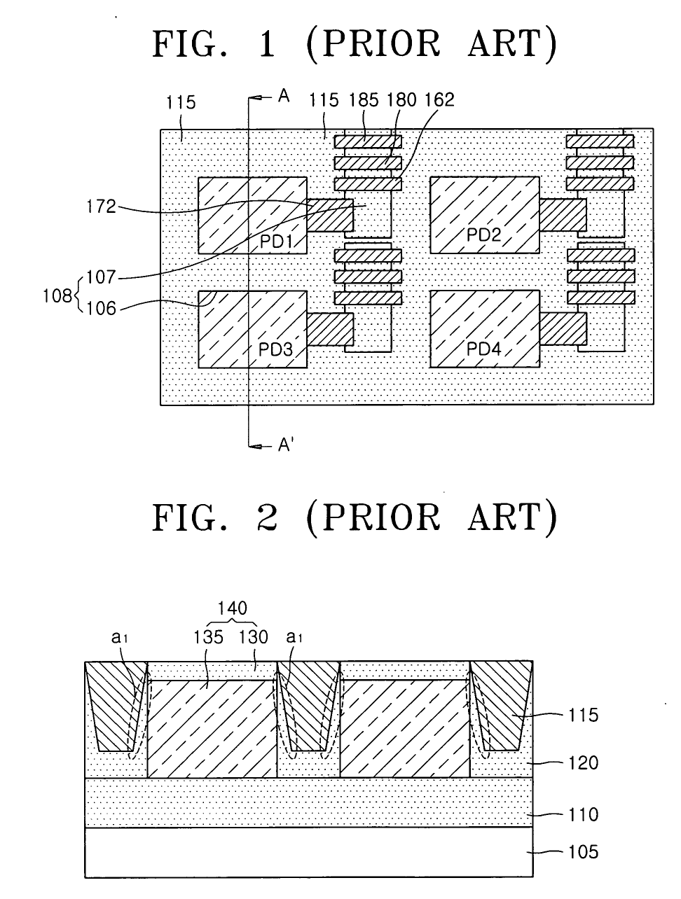

As described above, the CMOS image sensor according to an exemplary embodiment of the present invention includes the second device isolation region 217 doped with impurities, as opposed to the conventional device isolation region 115 of FIG. 2 formed of an insulating layer. The CMOS image sensor according to exemplary embodiments of the present invention can better reduce dark current than the conventional CMOS image sensor of FIG. 1.

Referring to FIG. 3, the control gates 262, 272, 280, and 285 are formed on the second active region 207. The control gates 262, 272, 280, and 285 are transistor gates for controlling the photodiode 240. In an exemplary embodiments of the present invention, control gates 262, 272, 280, and 285 comprise a reset gate, a transfer gate, a drive gate, and a select gate, respectively. The transfer gate 272 may control the transmission of electric charges generated by the photodiode 240, for example, electrons or holes, to a floating diffusion region 250. The reset gate 262 may reset the potential of the floating diffusion region 250 to a driving voltage. The drive gate 280 may function as a source follower receiving the potential of the floating diffusion region 250. The select gate 285 selects a pixel.

Referring to FIGS. 3 and 5, the reset gate 262 includes a reset gate electrode 260 and a reset gate insulating film 255. The reset gate electrode 260 may be formed of polysilicon, metal, or a combination thereof. The reset gate insulating film 255 may be an oxide film, a nitride film, or a combination thereof. A p-type well 225 doped with, for example, the p-type impurities is formed in the second active region 207 under the reset gate 262. In an exemplary embodiment of the present invention, a transistor including the reset gate 262 may be an n-type metal oxide semiconductor (NMOS) transistor.

A first threshold voltage adjustment region 245 for controlling a threshold voltage of the reset gate 262 is formed on the p-type well 225 under the control gate 262. The first threshold voltage adjustment region 245 is doped with the p-type impurities. An impurity doping density of the first threshold voltage adjustment region 245 may be increased to raise the threshold voltage of the reset gate 262, and the impurity doping density of the first threshold voltage adjustment region 245 may be reduced to lower the threshold voltage of the reset gate 262.

Referring to FIGS. 3 and 6, the control gate 272, e.g., the transfer gate 272, includes a transfer gate electrode 270 and a transfer gate insulating film 265. The p-type well doped with the p-type impurities is formed in the second active region 207 under the control gate 272. The photodiode 240 may be disposed on a side of the active region 208, and the floating diffusion region 250 may be disposed on the other side of the active region 208, with the control gate 272 interposed therebetween. The floating diffusion region 250 may be doped with the n-type impurities. In an exemplary embodiment of the present invention, a transistor including the control gate 272 is an NMOS transistor.

A second threshold voltage adjustment region 245′ doped with the p-type impurities is formed on the p-type well 225 under the control gate 272 to adjust the threshold voltage of the control gate 272. Electric charges generated by the photodiode 240 can move to the floating diffusion region 250 by turning on the control gate 272.

Referring to FIGS. 3, 5, and 6, the second active region 207 is surrounded by the first device isolation region 215 formed of an insulating layer. The first device isolation region 215 is interposed between the photodiodes 240 arranged in each row. For example, a right side of the first photodiode PD1 and a left side of the second PD2 and a right side of the third photodiode PD3 and a left side of the fourth photodiode PD4 are bounded by the first device isolation region 215. The photodiode 240 may be electrically insulated from the p-type well 225 by the first device isolation region 215, as illustrated in FIG. 5. A side of the floating diffusion region 250 may be bounded by the first device isolation region 215, as illustrated in FIG. 6.

The first device isolation region 215 may be surrounded by a channel stop region 220 of the semiconductor substrate 205. The channel stop region 205 may be doped with impurities of a type opposite to the type of impurities used to dope the floating diffusion region 250. The channel stop region 220 may contact the deep p-type well 210 thereunder.

The first device isolation region 215 may be a local oxidation of silicon (LOCOS) formed by oxidizing, for example, silicon or a shallow trench isolation (STI) formed by filing a trench with an insulating layer, for example, an oxide layer. The first device isolation region 215 may be a STI, for example, having superior device insulating characteristics. The STI is known for its superior performance in reducing a narrow width effect. The narrow width effect refers to a phenomenon in which a threshold voltage increases as a gate width narrows.

When the control gate 262 is turned on, a channel may be formed around the first threshold voltage adjustment region 245. The width of the channel is initially determined by the physical gap between the first device isolation regions 215 on both sides of the first threshold voltage adjustment region 245. However, if the first device isolation region 215 is an impurity region like the second device isolation region 217, the width of the channel is formed smaller than the physical gap due to the expansion of a depletion region, and the narrow width effect may become worse.

In the CMOS image sensor according to an exemplary embodiment of the present invention, the second active region 207 on which the control gates 262, 272, 280, and 285 are formed is bounded by the first device isolation region 215 formed of an insulating layer. The CMOS image sensor according to exemplary embodiments of the present invention can prevent the narrow width effect of transistors including the control gates 262, 272, 280, and 285. The second device isolation region 217 doped with impurities may be formed between the first active regions 206 or between the photodiodes 240 arranged in each column where the control gates 262, 272, 280, and 285 are not formed, and the generation of unnecessary electric charges between the photodiodes 240 arranged in each column can be suppressed, reducing dark current.

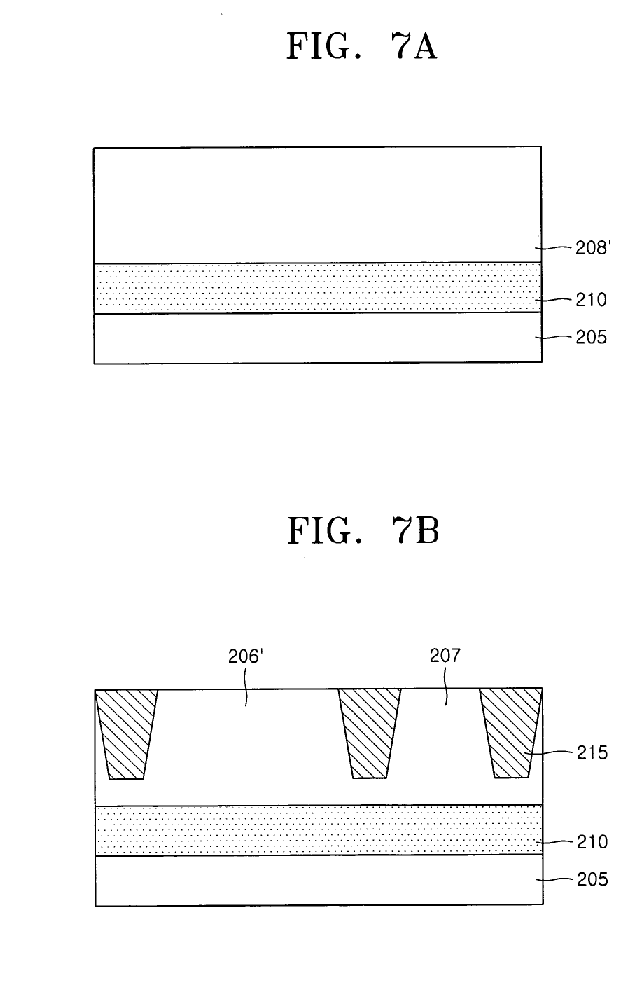

As described above with reference to FIGS. 3 through 6, a CMOS image sensor according to an exemplary embodiment of the present invention includes photodiodes 240 arranged in an array of rows and columns and the control gates 262, 272, 280 and 285 for each of the photodiodes 240. A method of fabricating the CMOS image sensor according to an exemplary embodiment of the present invention will now be described with reference to FIGS. 7A through 9B.

Referring to FIGS. 7A and 7B, the deep p-type well 210 is formed in the semiconductor substrate 205. For example, boron (B) or BF2 may be doped deeply into the semiconductor substrate 205 using an ion implanter. Then, the device isolation region 215 is formed and defines an active region 208′. To form the device isolation region 215, a trench (not shown) of a predetermined depth is formed, filled with an insulating layer (not shown), and planarized. The insulating layer may comprise, for example, a high-density plasma (HDP) or ozone oxide layer.

The active region 208′ includes a first active region 206′ and the second active region 207. The first active region 206′ includes a region where photodiodes are to be formed, and the second active region 207 is a region on which control gates are to be formed. The second active region 207 is connected to a side of the first active region 206′.

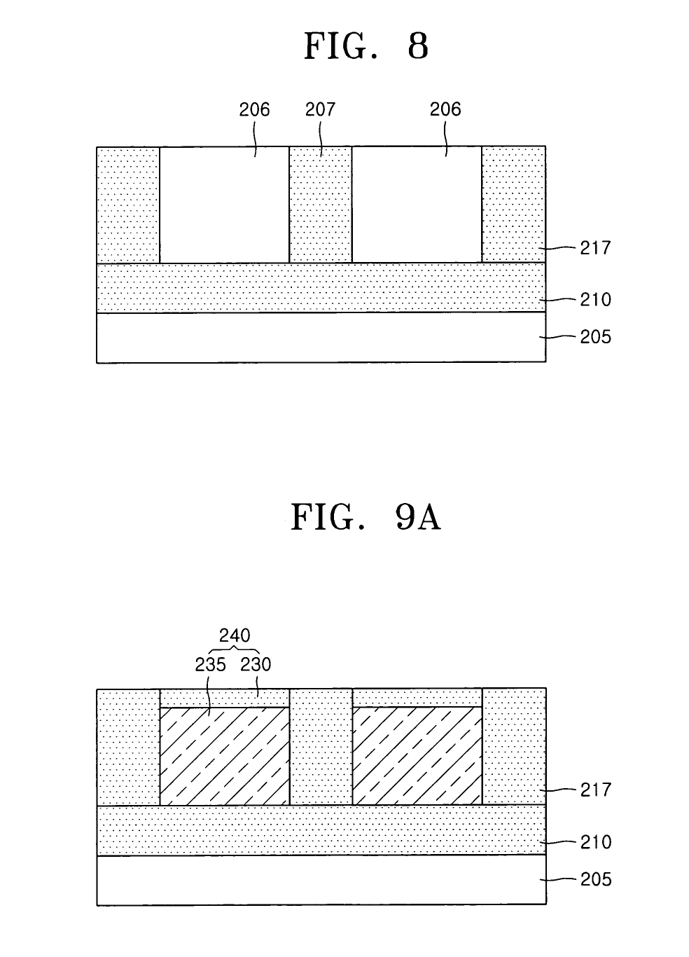

Referring to FIG. 8A, the second device isolation region 217 defining the first active region 206 and photodiode regions arranged in one direction to be separated from one another by a predetermined distance are formed in the active region 208′ of FIG. 7A. The first and second active regions 206 and 207 are defined by the first and second device isolation regions 215 and 217. The second device isolation region 217 may be formed by doping the semiconductor substrate 205 with impurities, for example, the p-type impurities. In an exemplary embodiment of the present invention, the first device isolation region 215 suppresses the narrow width effect, and the second device isolation region 217 suppresses the generation of dark current.

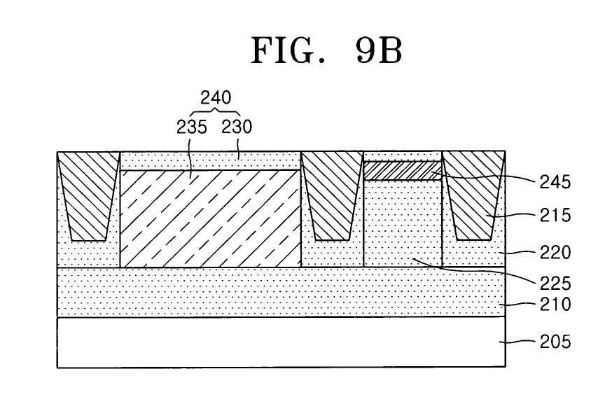

Referring to FIGS. 9A and 9B, the photodiodes 240 are formed in the photodiode region or the first active region 206. The photodiodes 240 may include the first conductive impurity region 230 and the second conductive impurity region 235 under the first conductive impurity region 230. The first conductive impurities may be the p-type impurities and the second conductive impurities may be the n-type impurities.

Before or after the photodiodes 240 are formed, the p-type well 225 may be formed on the second active region 207. The threshold voltage adjustment region 245 may be formed in the p-type well 225. Alternatively, the p-type well 225 and the second device isolation region 217 may be formed simultaneously. In this case, the p-type well 225 and the second device isolation region 217 may have the same impurity density. The channel stop region 220 surrounding the first device isolation region 215 may be formed either before or after the photodiode 240 is formed.

The fabrication of the CMOS image sensor may be completed using a conventional fabrication method known to those of ordinary skill in the art.

Although the exemplary embodiments of the present invention have been described in detail with reference to the accompanying drawings for the purpose of illustration, it is to be understood that the that the inventive processes and apparatus are not be construed as limited thereby. It will be readily apparent to those of ordinary skill in the art that various modifications to the foregoing exemplary embodiments can be made therein without departing from the scope of the invention as defined by the appended claims, with equivalents of the claims to be included therein.

What is claimed is:

1. A complementary metal-oxide semiconductor (CMOS) image sensor comprising:
a first active region of a semiconductor substrate in which a photodiode is formed;
a second active region of the semiconductor substrate connected to a first side of the first active region;
a first device isolation region of the semiconductor substrate comprising an insulating layer that surrounds the second active region and bounds the first side of the first active region and a second side of the first active region disposed opposite to the first side of the first active region; and
a second device isolation region of the semiconductor substrate bounding at least two opposite sides of the first active region without contacting the second active region, wherein the second device isolation region is doped with impurities.

2. The image sensor of claim 1, further comprising at least one control gate formed on the second active region.

3. The image sensor of claim 2, wherein the at least one control gate comprises a transfer gate controlling the transmission of electric charges by the photodiode.

4. The image sensor of claim 1, wherein the photodiode comprises an impurity region of a first conductivity type and an impurity region of a second conductivity type.

5. The image sensor of claim 4, wherein the second device isolation region is doped with impurities of the first conductivity type.

6. The image sensor of claim 5, wherein the impurities of the first conductivity type are p-type impurities and wherein the impurities of the second conductivity type are n-type impurities.

7. The image sensor of claim 1, wherein the semiconductor substrate is doped with the impurities of the first conductivity type and wherein the second device isolation region is doped with the impurities of the second conductivity type.

8. The image sensor of claim 1, wherein the first device isolation region is a shallow trench isolation formed by filling a trench with the insulating layer.

9. The image sensor of claim 1, wherein a well of a first conductivity type is formed in the first active region and wherein the second device isolation region is doped with the impurities of the first conductivity type.

10. A CMOS image sensor comprising:
a plurality of active regions of a semiconductor substrate comprising first active regions arranged in rows and columns and second active regions interposed between the first active regions arranged in each row and connected to the first active regions;
photodiodes formed in the first active regions;
at least one control gate formed on each of the second active regions;
a first device isolation region of the semiconductor substrate interposed between the second active regions and the photodiodes arranged in each row, wherein the first device isolation region comprises an insulating layer; and
a second device isolation region of the semiconductor substrate interposed between the photodiodes arranged in each row.

11. The image sensor of claim 10, wherein each of the photodiodes comprises an impurity region of a first conductivity type formed over an impurity region of a second conductivity type.

12. The image sensor of claim 11, wherein the second device isolation region is doped with impurities of the first conductivity type.

13. The image sensor of claim 12, wherein the impurities of the first conductivity type are p-type impurities and wherein the impurities of the second conductivity type are n-type impurities.

14. The image sensor of claim 10, wherein the first device isolation region is a shallow trench isolation formed by filling a trench with the insulating layer.

15. The image sensor of claim 10, wherein a first conductive well is formed in the second active region under the at least one control gate, and wherein the second device isolation region is doped with the impurities of the first conductivity type.

16. A method of fabricating a CMOS image sensor, the method comprising:
forming a first device isolation region defining an active region in a semiconductor substrate by burying an insulating layer in the semiconductor substrate;
defining photodiode regions disposed in one direction in the active region, forming a second device isolation region by doping regions between the photodiode regions with impurities, and forming an active region surrounded by the first device isolation region and the second device isolation region; and
forming photodiodes in the photodiode regions.

17. The method of claim 16, wherein the first device region is formed by forming a trench in the semiconductor substrate, filling the trench with the insulating layer, and planarizing the insulating layer.

18. The method of claim 16, wherein the second device isolation region is doped with impurities of a first conductivity type.

19. The method of claim 18, wherein each of the photodiodes comprises a region doped with the impurities of the first conductivity type formed over a region doped with impurities of a second conductivity type.

20. The method of claim 19, wherein the impurities of the first conductivity type are p-type impurities, and wherein the impurities of the second conductivity type are n-type impurities.
